(19) United States
(12) Patent Application Publication
(10) Pub. No.: US 2026/0304646 A1
(43) Pub. Date: Oct. 1, 2026

(54) FORMING A CIRCUIT BEARING STRUCTURE WITH DIELECTRIC INK

(71) Applicant: LCP MEDICAL TECHNOLOGIES, LLC, Rogers, MN (US)

(72) Inventor: James Rathburn, Rogers, MN (US)

(21) Appl. No.: 19/478,784

(22) PCT Filed: Apr. 26, 2024
(86) PCT No.: PCT/US2024/026573

§ 371 Date: Oct. 24, 2025

Related U.S. Application Data
(60) Provisional application No. 63/498,350, filed on Apr. 26, 2023.
(60) Provisional application No. 63/498,905, filed on Apr. 28, 2023.

(51) Int. Cl. H05K 3/46; C23C 24/10; H05K 1/03; H05K 1/09

(52) U.S. Cl. CPC H05K 3/4644; C23C 24/106; H05K 1/032; H05K 1/092; H05K 2201/0141

(57) ABSTRACT

Embodiments for a method of forming a circuit bearing structure are provided. The method includes depositing and curing dielectric ink around circuit features standing proud on a first surface of a first dielectric layer of a substrate, wherein depositing dielectric ink on the first surface includes covering the circuit features with dielectric ink and disposing a second dielectric layer on top of the dielectric ink prior to curing the dielectric ink, such that the dielectric ink is disposed between the first dielectric layer and the second dielectric layer, wherein curing the dielectric ink bonds the second dielectric layer to the first dielectric layer.

### RELATED APPLICATIONS

This application claims the benefit of U.S. Provisional Application No. 63/498,350, filed on Apr. 26, 2023, and entitled “LOW LOSS DIELECTRIC LIQUIDOUS OR INK DEPOSITION WITH LIQUID CRYSTAL POLYMER OF PTFE LOADING OPTION FOR PRINTED CIRCUIT FABRICATION”, and of “U.S. Provisional Application No. 63/498,905, filed on Apr. 28, 2023, and entitled “LOW TEMPERATURE, LOW PRESSURE LAMINATION OF LIQUID CRYSTAL POLYMER MULTI-LAYER HIGH PERFORMANCE CIRCUIT STRUCTURES”, both of which are hereby incorporated herein by reference.

### BACKGROUND

Traditional printed circuits are often constructed in either rigid or flexible formats. In a rigid format, the printed circuit board (PCB) is a laminate of materials including circuits that when completed is stiff and cannot bend significantly without damage. Flexible circuits have become popular more recently in many applications where the ability to bend the circuit to connect one member of a system to another has some benefit. These flexible circuits are made in a similar manner to rigid PCBs, where layers of circuitry and dielectric are laminated. The main difference is the material set used for construction. Typical flexible circuits start with a polymer film that is clad, laminated, or deposited with copper. A photolithography image with the desired circuit geometry is printed onto the copper, and the film is etched to remove the unwanted materials. The films are processed similar to that of rigid PCBs with a series of imaging, masking, drilling, via creation, plating, trimming, etc. The resulting circuit is flexible in such a way that as it is bent, the polymer film bends and supports the copper circuitry in a way that it does not crack or break. These circuits are solderable and can have devices attached to provide some desired function. They are used in many electronic systems such as notebook computers, medical devices, displays, handheld devices, automobiles, and aircraft. These flexible materials can be used in high frequency applications where the material set and design features can often provide better electrical performance than a comparable rigid circuit.

Both rigid and flexible circuits are connected to the system in a variety of ways. In most cases, a portion of the circuitry is exposed to create a connection point in terminal. Once exposed, the terminal can be connected to another circuit or component by soldering, conductive adhesive, thermosonic welding, pressure, or some sort of connector.

In general, the terminals are located on an end of the circuit, where edge traces are exposed or in some cases an area array of terminals are exposed. Often there is some sort of mechanical enhancement at or near the connection to prevent the joints from being disconnected during use or flexure.

Most printed circuit constructions utilize dielectrics and composites in sheet or film form, with processing steps that rely on lamination and bonding materials in sheet form to create the multi-layer stacks. As circuits and the spaces between them get smaller, it becomes increasingly difficult to control the impedance environment of the circuits. The characteristic impedance of a circuit is dictated by the circuit geometry itself, the dielectric properties of the material set surrounding the circuit, and the dielectric separation to the nearest reference plane. Existing commercially available material sets are typically provided in specific thicknesses that are held to a certain tolerance, which may be a fairly wide range depending on manufacturing variability. These material sets can also be relatively thick due to the desire for ease of handling during the manufacturing process. In some cases, a build-up film, such as Ajinomoto Build-Up Film® (ABF) produced by Ajinomoto Fine-Techno Co., Inc., is used for fine line and space substrate applications, where the circuit pattern is laser ablated into the film and plated with electroless copper and then electrolytic copper to create the circuit pattern. In this case, the dielectric film itself acts as the base dielectric and does not require a bonding layer with the next layer of ABF. ABF is one alternative that uses itself as the dielectric bearing circuits, with liquid crystal polymer (LCP) and polytetraflouroethylene (PTFE) (Teflon®) among other materials as well as many other lower loss materials that are a mixture of resin epoxy, ceramic, glass, etc.

To add additional layers to such a dielectric sheet, a lamination process is used that applies heat and pressure to the material stack to provide a reliable bond between the layers. If circuits are formed on dielectric sheets that stand proud of the surface, the existing processes of adding layers on top of the circuits is such that the bond materials must flow enough to fill in between the circuit traces standing proud on the dielectric sheets. The bond material must also create a strong enough bond to provide a reliable circuit stack that does not separate or delaminate. These existing processes often require a vacuum environment to remove any air from the process such that entrapment is avoided, which can cause delamination points. The high temperature and pressure of lamination can also add stress to the circuit stack which can result in bowing or out of flat conditions during subsequent processing or final assembly with solder reflow.

### BRIEF DESCRIPTION

Embodiments for a method of forming a circuit bearing structure are provided. The method includes depositing and curing dielectric ink around circuit features standing proud on a first surface of a first dielectric layer of a substrate.

### DRAWINGS

Understanding that the drawings depict only exemplary embodiments and are not therefore to be considered limiting in scope, the exemplary embodiments will be described with additional specificity and detail through the use of the accompanying drawings, in which:

FIGS. 1A-1H are cross-sectional cut-away views of example stages in a process of creating a circuit bearing structure using dielectric ink;

FIGS. 2A and 2B are cross-sectional cut-away views of example stages in a process of adding a layer to a circuit bearing structure formed in accordance with the process of FIGS. 1A-1G;

FIG. 3 is a cross-sectional cut-away view of another example circuit bearing structure formed using dielectric ink; and

FIG. 4 is a cross-sectional cut-away view of yet another example circuit bearing structure formed using dielectric ink.

### DETAILED DESCRIPTION

The subject matter described herein leverages the principles of traditional circuit fabrication, while using alternate dielectric materials in ink form to create a multi-layer low loss circuit stack. The dielectric ink provides an alternative or complement to existing sheet-based dielectric multi-layer circuit fabrication.

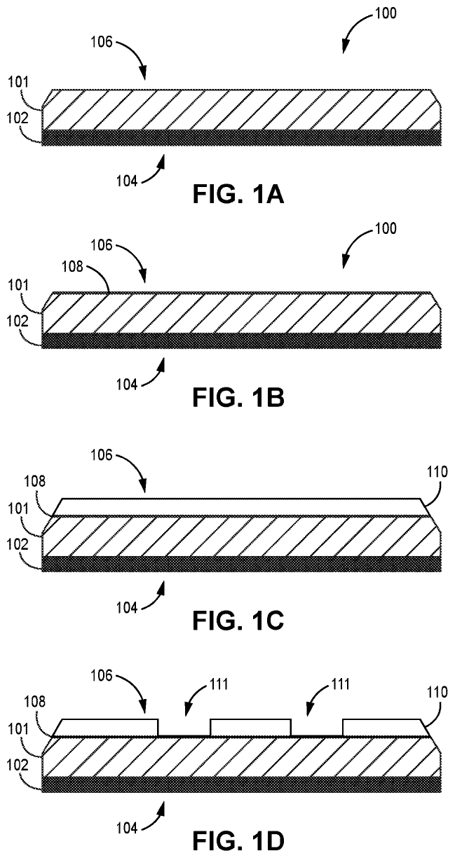

FIG. 1A is a cross-sectional cut-away view of an example portion of a substrate 100 onto which a circuit can be fabricated as described herein. The substrate 100 can include one or more dielectric layers 101. Each dielectric layer 101 can be composed of a dielectric material, such as liquid crystal polymer (LCP), polyimide, or Ajinomoto Build-Up Film® (ABF) produced by Ajinomoto Fine-Techno Co., Inc. LCP has many benefits from an electrical and mechanical standpoint. It has a lower dielectric constant than traditional PCB dielectric materials, can be processed to accept direct metal deposition, does not absorb moisture, and has low loss at high frequencies. The dielectric layer 101 can be a preformed film, or can be injection molded, printed, or compression molded to form a planar film having a desired thickness. In an example, the dielectric layer 101 is less than 200 microns thick. The composition of each dielectric layer 101 can be selected to have desired dielectric properties. One or more of the dielectric layers 101 can be clad with a copper layer 102 on a first surface 104 and have the bare dielectric layer exposed on a second surface 106, reverse of the first surface 104. The copper layer 102 can be deposited or laminated onto a dielectric layer 101 or can be a copper film that is laminated to a dielectric layer 101 and etched down to a thickness of 10 microns or less. Although FIG. 1A illustrates substrate 100 having a single dielectric layer 101 with no circuit features formed therein, in other examples the substate 100 includes more than one dielectric layer (e.g., a stack of dielectric layers) each of which may or may not have circuit features defined therein or thereon.

FIGS. 1B-1F are cross-sectional views of the example stages of forming a circuit on the substrate of FIG. 1A. In FIG. 1B, a layer of metal (e.g., copper) 108 is deposited on the second surface 106 of the dielectric layer 101. The metal layer 108 can be 10 microns or less thick, for example, between about 1 and 5 microns thick. The metal layer 108 can be formed by coating the second surface 106 of the dielectric layer 101 with particle-free metal ink. Particle-free metal ink is a liquid that includes metal ions, metal molecules, and/or metal salts along with volatile solvents in a solution. The metal ions, molecules, and/or salts can include copper and/or palladium and have a size less than 1 micron. The surface of the dielectric layer 101, can be conditioned to accept particle-free metal ink prior to coating. Conditioning the dielectric layer 101 can include roughening the surface to improve the bond between the dielectric and the particle-free ink. Some dielectrics have a smooth surface that can be adhesion resistant. Conditioning such a surface with O₂ plasma, permanganate, or applying a primer can create a slight porosity, roughened, or activated surface that improves a chemical and mechanical bond and increases the peel strength of the bond to reduce risk of separation during use or temperature excursions.

Once the particle-free ink is coated on the surface, the particle-free metal ink can be sintered to drive metal deposition out of solution to create a layer of solid metal 108 on the second surface 106 of the dielectric layer 101. Sintering can include treating the particle-free metal ink with a thermal excursion or plasma atmosphere, which causes the metal in the particle-free metal ink to deposit as the solvent evaporates. The resultant deposition is ideally entirely bulk metal, although some oxide may be present depending on the purity of the solution and the atmosphere as the solvent is evaporated.

In an alternative example, the metal layer 108 can be formed via known electroless copper deposition techniques or can be a copper film that is laminated to the dielectric layer 101 and etched down to a thickness of 10 microns or less.

In FIG. 1C, a resist 110 is deposited on the second surface 106 on top of the metal layer 108. The resist 110 can be composed of any suitable material. In FIG. 1D, the resist 110 is imaged and stripped to cure portions of the resist that are not overtop of desired circuit locations 111 and to remove portions of the resist that are overtop of desired circuit locations 111, thereby exposing the metal layer 108 in the desired circuit locations 111.

In FIG. 1E, the resist 110 is imaged and stripped and copper is added in the recesses formed in the resist 110 to form circuit features. In an example, the copper is added via electroplating with the layer of metal 108 as the electrical bus. In this example, the resist 110 restricts the deposition of copper to the recesses, forming circuit features 116 on top of the dielectric layer 101. In an alternative example, copper can be added to the recesses via additional coating of the surfaces of the recesses with particle-free metal ink and sintering.

In FIG. 1F, the resist 110 is stripped away after plating and the layer of metal 108 outside of the circuit features 116 is also etched away. This leaves circuit features 116 standing proud on the surface of the dielectric layer 101 without metal extending between adjacent circuit features 116.

In FIG. 1G, dielectric layer 112 (e.g., low loss dielectric) is formed by depositing dielectric in ink form between the circuit features 116. The dielectric ink can be deposited on the substrate with any suitable 3D printing, ink jet printing, aerosol jet printing, or spray coating technology. The dielectric ink can include one or more of liquid-form liquid crystal polymer (LCP), polyimide, or Ajinomoto Build-Up Film® (ABF) produced by Ajinomoto Fine-Techno Co., Inc. Such a dielectric ink (e.g., liquid LCP) can be fine particles of dielectric (e.g., LCP) suspended in a liquid carrier that when cured provides a binder to hold the particles in position. The fill percentage should be great enough to create a deposition that has the properties of the powder being dominant and approaching the aggregate properties of pure LCP, PTFE, ceramic or combinations thereof. In other examples, a polymer is dissolved in a solvent and then deposited as desired with the solvent driven off to leave behind the polymer.

The dielectric ink deposition can be performed in multiple layers that are built up to the desired thickness. In an example, a layer is cured prior to depositing the next layer of dielectric ink. This process can be repeated as many times as necessary to achieve a desired final thickness. In an alternative example, multiple wet layers of dielectric ink can be deposited without curing in between. In such an alternative example, a bead-dam can be provided at the edges of the desired dielectric to contain any flow. In an example, the dielectric ink is deposited overtop (i.e., covering) the circuit features 116. After drying, the dielectric ink forms a solid dielectric 112 on the second surface 106 of the dielectric layer 101 between and optionally overtop of the circuit features 116.

FIG. 1H is a cross-sectional view of an optional step in which an additional dielectric layer 114 is added overtop of the circuit features 116 and the dielectric ink of dielectric layer 112 acts as a bonding agent. In such a step, dielectric (e.g., low loss dielectric) in ink form is deposited between the circuit features 116. In an example, the dielectric ink is deposited overtop (i.e., covering) the circuit features 116. An additional solid dielectric layer 114 is disposed on top of the ink form dielectric (112), such that the ink form dielectric is disposed between the additional dielectric layer 114 and the dielectric layer 101. The ink form dielectric is then cured with temperature and pressure to solidify and physically bond the additional dielectric layer 114 to the dielectric layer 101 while also encapsulating the circuit features 116. Advantageously, using dielectric in ink form reduces the pressure and temperature that is applied during lamination as compared to existing lamination techniques with sheet-based bonding layers. Thus, the dielectric layers 101, 114 on either side of the dielectric ink (112) are less likely to deform, providing better reliability for circuits in the resulting structure. Although the circuit features 116 of FIG. 1H are created using the process described in FIGS. 1A-1G, in other examples the circuit features 116 can be created by selective etching of a layer of copper.

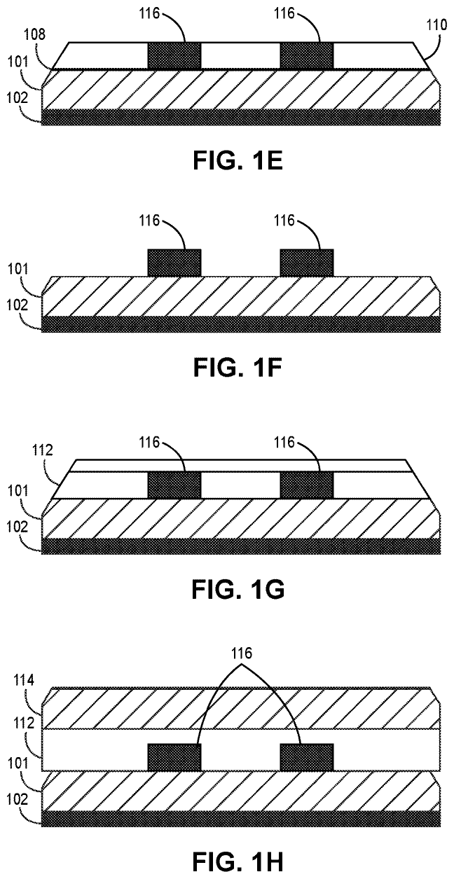

FIGS. 2A and 2B are cross-sectional cut-away views of another example structure (e.g., PCB) including a core 202 in which additional layers 204, 206 are added to both sides of the core 202. One or more (e.g., all) of the additional dielectric layers 204, 206 can have a thickness of less than 200 microns. The core 206 includes circuit features and vertical solid copper vias for creating the desired circuit network through the stack and terminating to surface mounting pads (not shown). Each additional layer 204, 206 can be bonded to the core 202 using dielectric ink 208 as the bonding agent as discussed with respect to FIG. 1H.

The process described in FIGS. 1A-1H and FIGS. 2A and 2B can be repeated multiple times to create a structure (e.g., PCB) having multiple layers of circuits therein. One or more (e.g., all) of the additional dielectric layers can have a thickness of less than 200 microns. Additional circuit features can then be formed in or on each dielectric layer using any of the processes described herein.

Vertical vias can be formed through each such bonding layer 210 with laser ablation. The side walls of recesses formed through a bonding layer 210 with laser ablation can be coated with copper (e.g., via electroless plating) and then additional copper can be electrolytically plated thereon to create a solid copper via electrically coupling an upper circuit to a lower circuit.

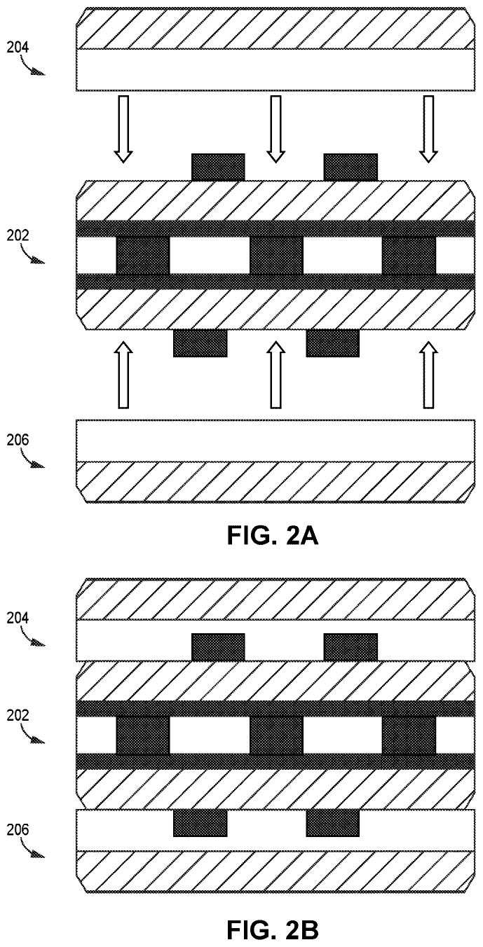

FIG. 3 is a cross-sectional cut-away view of an example structure having circuit features 302 formed in a dielectric layer 304. Such a structure can be formed by printing dielectric ink in multiple passes and in select locations such that the dielectric layer 304 is built up on a base 306 (e.g., copper layer). The location in which the dielectric ink is printed onto the base 306 for each pass is controlled to form recesses for the circuit features 302. The recesses can have any depth or shape that can be printed. Once the dielectric layer 304 is printed, copper can be deposited into the recesses to form the circuit features 302 (e.g., traces and/or vias). The copper can be deposited in any suitable including with electroless and electrolytic plating. Particle-free metal ink can also be used as described in PCT Application No. PCT/US2024/026203, filed on Apr. 25, 2024, and titled “Forming a Circuit Bearing Structure with Particle-Free Metal Ink”, which is hereby incorporated herein by reference. Although FIG. 3 illustrates the base 306 is shown as a stand-alone copper layer, in other examples, the base 306 can be a surface of an existing circuit stack. Alternatively, dielectric ink can be printed onto a base 306 to form a dielectric layer without circuit features therein.

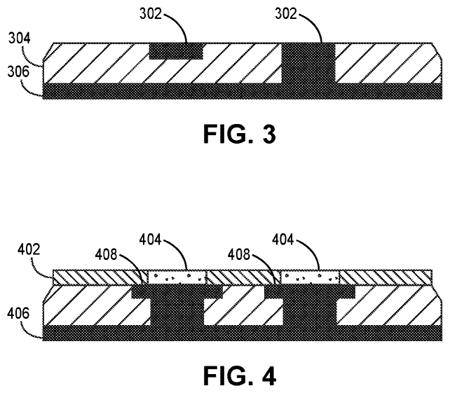

FIG. 4 is a cross-sectional cut-away view of an example structure in which dielectric ink 402 is used as a mask for creating surface mount pads 404. The process described with respect to FIG. 3 can be used to create recesses that are filled with a conductive material (e.g., gold, silver, or palladium) for the surface mount pads 404. The conductive material can be a metal ink that is printed into the recesses. The dielectric mask 402 can be deposited on a dielectric layer 406 having circuit features 408 defined therein.

LCP, PTFE, ceramic, or other particles can be included in any of the dielectric ink described herein to create composite electrical and mechanical properties for the resulting dielectric. Such a suspension of particles in the dielectric ink may benefit a laser ablation process into the resulting dielectric, especially if the dielectric ink would be optically transparent with limited response to UV laser ablation if the particles were not included.

Although a certain type, size, and number of dielectric layers and circuit bearing structures are shown in FIGS. 1-4 herein, it should be understood that any number, size, or type of layers and/or circuit bearing structures in or on a layer can be created using the processes described herein, unless specifically limited by the corresponding description.

There are many benefits to the subject matter described herein. The subject matter described herein enables circuit geometries to get smaller and resulting dielectric thickness layers to be thinner due by depositing low loss dielectric in a thin layer. Additionally, particles can be included in the dielectric ink to enhance electrical or mechanical properties. The dielectric ink naturally fills spaces between circuit features standing proud on a surface without the heat or lamination required for existing techniques. It also fills well between circuit traces having higher aspect ratios, which is difficult to accomplish with existing techniques. Many of these benefits come from the ability to print a dielectric or bonding layer rather than having to laminate a dielectric or bonding sheet. A dielectric or bonding layer can be formed with dielectric ink using lower heat and pressure than corresponding lamination using a dielectric or bonding sheet.

What is claimed is:

1. A method of forming a circuit bearing structure, the method comprising:
providing a substrate having a first dielectric layer defining a first surface and circuit features standing proud on the first surface;
depositing dielectric ink on the first surface around the circuit features; and
curing the dielectric ink.

2. The method of claim 1, wherein depositing dielectric ink on the first surface includes covering the circuit features with dielectric ink.

3. The method of claim 1, comprising:
disposing a second dielectric layer on top of the dielectric ink prior to curing the dielectric ink, such that the dielectric ink is disposed between the first dielectric layer and the second dielectric layer, wherein curing the dielectric ink bonds the second dielectric layer to the first dielectric layer.

4. The method of claim 1, wherein the dielectric ink includes particles suspended therein.

5. The method of claim 4, wherein the particles in the dielectric ink provide laser response to the dielectric layer formed from the dielectric ink after curing, such that a dielectric layer cured from dielectric ink without such particles would be optically transparent, and a dielectric layer cured from dielectric ink with such particles can be ablated with the laser.

6. The method of claim 4, wherein the particles include liquid crystal polymer (LCP) particles.

7. The method of claim 1, wherein the dielectric ink includes liquid-form liquid crystal polymer (LCP).

8. A method of forming a circuit bearing structure, the method comprising:
printing dielectric ink on a base, wherein printing forms a dielectric layer on the base, the dielectric layer defining one or more recesses therein; and
depositing an electrically conductive material in the one or more recesses to form circuit features in the dielectric layer.

9. The method of claim 8, wherein the electrically conductive material is copper.

10. The method of claim 8, wherein the electrically conductive material is one of silver, gold, or palladium.

11. The method of claim 8, wherein the electrically conductive material is metal ink.

12. The method of claim 8, wherein depositing an electrically conductive material includes electroplating copper in the one or more recesses.

13. The method of claim 8, wherein the dielectric ink includes liquid-form liquid crystal polymer (LCP).
